(19) United States
(12) Patent Application Publication
(10) Pub. No.: US 2026/0202564 A1
(43) Pub. Date: Jul. 16, 2026

(54) MOVING-COIL GEOPHONE ZERO-PHASE CORRECTOR BASED ON STATE VARIABLE SHAPER

(71) Applicant: Jilin University, Changchun City (CN)

(72) Inventors: Hongyuan YANG, Changchun City (CN); Ruojin LI, Changchun City (CN); Yun LONG, Changchun City (CN); Ang LI, Changchun City (CN); Can LIU, Changchun City (CN); Fan ZHENG, Changchun City (CN); Huaizhu ZHANG, Changchun City (CN); Linhang ZHANG, Changchun City (CN); Yilin WANG, Changchun City (CN)

(21) Appl. No.: 19/411,615

(22) Filed: Dec. 8, 2025

(30) Foreign Application Priority Data
Jan. 14, 2025 (CN) 202510052323.3

(51) Int. Cl. G01V 1/18; H03F 3/45

(52) U.S. Cl. CPC G01V 1/182; H03F 3/45475

(57) ABSTRACT

A moving-coil geophone zero-phase corrector based on a state variable shaper is provided. The zero-phase corrector includes a state variable shaper module, a differential-to-single-ended module, and a single-ended-to-differential module. After a moving-coil geophone signal is input as a differential signal, the differential-to-single-ended module converts the signal into a single-ended signal suitable for filtering, the high-pass filter, band-pass filter, and low-pass filter in the state variable shaper module correct the phase characteristic of the geophone's frequency response to a zero-phase attribute, and finally, the single-ended-to-differential module converts the single-ended signal back into a differential signal for output.

### CROSS-REFERENCE TO RELATED APPLICATIONS

This application claims priority to Chinese Patent Application No. 202510052323.3, filed on Jan. 14, 2025, the contents of which are hereby incorporated by reference.

### TECHNICAL FIELD

The present disclosure relates to the field of geophysical signal processing, and in particular to a zero-phase correction for a moving-coil geophone. The present disclosure is specifically applied in fields such as analog signal processing for moving-coil geophones, and is capable of performing zero-phase correction on output signals from moving-coil geophones with different phase characteristics.

### BACKGROUND

A seismic sensor is a core component in seismic exploration, mainly including moving-coil geophones, micro-electro-mechanical systems (MEMS), piezoelectric sensors, and pendulum broadband seismometers. The moving-coil geophone is widely used in geophysical detection due to the high sensitivity and low mechanical noise. The mechanical structure of the moving-coil geophone is shown in FIG. 1. The moving-coil geophone utilizes the relative motion between the inertial mass and the housing, causing the coil to cut magnetic lines of force in the magnetic field, generating an electromotive force across the coil, thereby converting ground vibration into an electrical signal. Thus, the moving-coil geophone has extremely high sensitivity and may detect minute ground vibrations. The output signal is a differential voltage signal, and the signal frequency band is mainly distributed between 5 Hertz and 300 Hertz. However, due to the different frequency response characteristics of electronic components, the output voltage signal of the moving-coil geophone exhibits a phase delay. Because the moving-coil geophone inherently possesses the characteristics of a second-order high-pass filter, as shown in FIG. 2, the lower the frequency, the greater the phase delay, and the phase delay may exceed 100 degrees and even approach phase inversion, which is particularly evident below 100 Hertz. In seismic data acquisition and processing, phase delay in seismic data often seriously affects data processing results, and avoiding phase distortion through software correction may not effectively remove the phase delay, thereby affecting the quality and reliability of seismic data acquisition.

The state variable shaper is a zero-phase correction circuit composed of an adder and two integrators. At different output ports, the state variable shaper may output the effects of a high-pass filter, band-pass filter, and low-pass filter, corresponding to different phase changes. By forming linear combinations through summation with different multiplication factors, the state variable shaper compensates for the phase-delayed portion of the output signal, thereby correcting the phase of the output signal. Through dynamic adjustment of state variables, a filter with a specific frequency domain response may be designed to achieve precise phase correction. The filter also possesses a certain robustness against variations in component parameters and non-ideal circuit characteristics, making the filter suitable for processing analog signals from moving-coil geophones and providing a potential solution to the output phase delay of moving-coil geophones.

### SUMMARY

Aiming at the problem of output phase delay in moving-coil geophones, the present disclosure proposes a moving-coil geophone zero-phase corrector based on a state variable shaper. The moving-coil geophone zero-phase corrector based on the state variable shaper is designed to correct the signal phase of the moving-coil geophone to 0 degrees, and by adjusting circuit parameters such as resistance values, to achieve zero-phase correction for the frequency response of moving-coil geophones with different phase characteristics, while also considering power consumption requirements by offering a selectable single-supply or dual-supply mode.

The technical scheme adopted by the present disclosure is as follows.

A moving-coil geophone zero-phase corrector based on a state variable shaper is formed by connecting a differential-to-single-ended module, a state variable shaper module, a single-ended-to-differential module, and a single-supply and dual-supply mode selection module.

Among them, the system frequency characteristic of the state variable shaper module only considers 5 Hertz to 300 Hertz. The state variable shaper module includes a high-pass filter, a band-pass filter, and a low-pass filter. The high-pass filter includes an adder U1. The band-pass filter includes an integrator U2 and an inverter U4. The low-pass filter includes an integrator U3.

The adder U1 of the high-pass filter includes an operational amplifier, a resistor R1, and a resistor R2. The resistor R1 serves as a feedback resistor connecting an inverting input terminal of the operational amplifier to an output terminal of the integrator U3. The resistor R2 connects an inverting input terminal of the adder U1 to an output terminal of the operational amplifier. The output terminal of the operational amplifier serves as an output port of the high-pass filter, and a phase at the output port is substantially zero.

The integrator U2 of the band-pass filter includes the operational amplifier, a resistor R3, a resistor R4, and a capacitor C1. The resistor R3 connects an output terminal of the adder U1 to the inverting input terminal of the operational amplifier. The resistor R4 and the capacitor C1 are connected in parallel as the feedback resistor and a feedback capacitor between the inverting input terminal and the output terminal of the operational amplifier, forming an inverting integrator. An output terminal of the integrator U2 exhibits a frequency characteristic of the band-pass filter and provides a phase lead of approximately 90 degrees in the wide frequency band range above 5 Hertz. The output terminal of the integrator U2 is connected to the inverter U4. The inverter U4 includes the operational amplifier, a resistor R7, a resistor R8, and a resistor R24. The resistor R7 connects the inverting input terminal of the operational amplifier to the output terminal of the integrator U2. The resistor R24 connects a non-inverting input terminal of the operational amplifier to an input reference voltage or ground. The resistor R8 serves as the feedback resistor connecting the inverting input terminal and the output terminal of the operational amplifier. The constituted inverter U4 ensures a band-pass filter phase characteristic unaltered.

The integrator U3 of the low-pass filter includes the operational amplifier, a resistor R5, a resistor R6, and a capacitor C2. The resistor R5 connects the output terminal of the integrator U2 to the inverting input terminal of the operational amplifier. The resistor R6 and the capacitor C2 are connected in parallel as the feedback resistor and the feedback capacitor between the inverting input terminal and the output terminal of the operational amplifier. The output terminal of the integrator U3 exhibits a frequency characteristic of the low-pass filter and provides a phase lead of approximately 180 degrees in the wide frequency band range above 5 Hertz.

Outputs of the high-pass filter, the band-pass filter, and the low-pass filter are connected to a resistor R9, a resistor R10, and a resistor R11 respectively. The resistors R9, R10, and R11 serve as resistors determining weighting coefficients for summing the low-pass, band-pass, and high-pass filters respectively to set filter multiplication factors for summation. The resistors R9, R10, and R11 are connected to an adder U5 and an inverter U6.

A resistor R12 in the adder U5 serves as a feedback resistor connecting the output terminal and the inverting input terminal of the operational amplifier in the adder U5, determining an amplification factor during the summation. A resistor R21 connects the non-inverting input terminal of the operational amplifier to the input reference voltage or the ground.

The inverter U6 ensures phase stability despite adder presence. The inverter U6 includes the operational amplifier, a resistor R13, a resistor R14, and a resistor R22. The resistor R13 connects the inverting input terminal of the operational amplifier to an output terminal of the adder U5. The resistor R22 connects the non-inverting input terminal of the operational amplifier to the input reference voltage or the ground. The resistor R14 serves as the feedback resistor connecting the inverting input terminal and the output terminal of the operational amplifier.

A transfer function of the state variable shaper module is as follows:

$$H ( s ) = K 1 * {H}_{H} ( s ) + K 2 * {H}_{B} ( s ) + K 3 * {H}_{L} ( s ) \qquad ( 1 )$$

In equation (1), s represents a frequency in a Laplace transform domain. K1, K2, and K3 are summation coefficients for the high-pass, band-pass, and low-pass filters respectively. Different summation coefficients correspond to different linear combinations. By changing the summation coefficients, a transfer function constructed by a circuit is altered to achieve phase characteristic correction for an output frequency response of different geophones. The summation coefficients K1, K2, and K3 adhere to a following relationship:

$$\{ \begin{matrix}K 1 = \frac{{R}_{12}}{{R}_{11}} \\ K 2 = \frac{{R}_{12}}{{R}_{10}} \\ K 3 = \frac{{R}_{12}}{{R}_{9}}\end{matrix} \qquad ( 2 )$$

Among them, R9 represents a resistance value of the resistor R9, R10 represents a resistance value of the resistor R10, and R11 represents a resistance value of the resistor R11.

In equation (1), H_{H}(s), H_{B}(s), and H_{L}(s) are transfer functions of the high-pass filter, band-pass filter, and low-pass filter respectively, expressed as:

$${H}_{H} ( s ) = \frac{\frac{{R}_{1} + {R}_{2}}{{R}_{1}} ( {R}_{6} {C}_{2} s + 1 ) ( {R}_{4} {C}_{1} s + 1 )}{( {R}_{6} {C}_{2} s + 1 ) ( {R}_{4} {C}_{1} s + 1 ) + \frac{{R}_{2} {R}_{4} {R}_{6}}{{R}_{1} {R}_{3} {R}_{5}}} \qquad ( 3 )$$

$${H}_{B} ( s ) = \frac{- \frac{{R}_{1} + {R}_{2}}{{R}_{1}} \frac{{R}_{4}}{{R}_{3}} ( {R}_{6} {C}_{2} s + 1 )}{( {R}_{6} {C}_{2} s + 1 ) ( {R}_{4} {C}_{1} s + 1 ) + \frac{{R}_{2} {R}_{4} {R}_{6}}{{R}_{1} {R}_{3} {R}_{5}}} \qquad ( 4 )$$

$${H}_{L} ( s ) = \frac{\frac{{R}_{1} + {R}_{2}}{{R}_{1}} \frac{{R}_{4}}{{R}_{3}} \frac{{R}_{6}}{{R}_{5}}}{( {R}_{6} {C}_{2} s + 1 ) ( {R}_{4} {C}_{1} s + 1 ) + \frac{{R}_{2} {R}_{4} {R}_{6}}{{R}_{1} {R}_{3} {R}_{5}}} \qquad ( 5 )$$

In transfer functions equations (3) to (5), C1 represents a capacitance of the capacitor C1, C2 represents a capacitance of the capacitor C2, R1 represents a resistance value of the resistor R1, R2 represents a resistance value of the resistor R2, R3 represents a resistance value of the resistor R3, R4 represents a resistance value of the resistor R4, R5 represents a resistance value of the resistor R5, and R6 represents a resistance value of the resistor R6.

H₁(s) represents a target transfer function used for zero-phase correction, and H₂(s) represents a transfer function after cascading the moving-coil geophone zero-phase corrector, expressed as:

$${H}_{1} ( s ) = \frac{{s}^{2} + 2 {ξ}_{0} {ω}_{0} s + {ω}_{0}^{2}}{{s}^{2} + 2 {ξ}_{1} {ω}_{1} s + {ω}_{1}^{2}} \qquad ( 6 )$$

$${H}_{2} ( s ) = \frac{{A}_{0} {s}^{2}}{{s}^{2} + 2 {ξ}_{1} {ω}_{1} s + {ω}_{1}^{2}} \qquad ( 7 )$$

In equation (6), ω₀ and ξ₀ are a cutoff frequency and a damping ratio of a transfer function of a moving-coil geophone respectively. ω₁ and ξ₁ are a cutoff frequency and a damping ratio of a transfer function of a zero-phase correction circuit respectively. In equation (7), A₀ is a gain of the transfer function of the moving-coil geophone.

H(s)=H₁(s) is set, and reasonable design and selection of resistor and capacitor parameters are combined, then the parameters C1, C2, R1, R2, R3, R4, R5, R6, R9, R10, R11, K1, K2, and K3 in above transfer function equations are solved, thus zero-phase correction of a geophone is enabled using solved circuit parameters.

A phase characteristic φ₂(ω) of the transfer function H₂(s) after cascading the geophone and the zero-phase correction circuit is set to have a phase magnitude of ε at 5 Hertz, as follows:

$${φ}_{2} ( ω ) = arctan ( - \frac{2 {ξ}_{1} {ω}_{1} ω}{{ω}_{1}^{2} - {ω}^{2}} ) = ε$$

With ξ₁ and ε known, ω₁ is solved to determine the target transfer function H₁(s) for the zero-phase correction.

The differential-to-single-ended module includes the operational amplifier, a resistor R15, a resistor R16, a resistor R17, and a resistor R18. The resistor R15 is connected to a positive input signal terminal and is connected in parallel with the resistor R16 to the non-inverting input terminal of the operational amplifier. The resistor R16 is connected to the ground or a reference voltage. The resistor R17 is connected to a negative input signal terminal and is connected in parallel with the resistor R18 to the inverting input terminal of the operational amplifier. A single-ended signal is input to the state variable shaper module. Resistance values of the resistors R15, R16, R17, and R18 are equal.

The single-ended-to-differential module includes an inverting proportional amplifier. A single-ended output signal is directly connected to a positive output terminal, and an other path of the single-ended output signal is connected to a negative output terminal through the inverting proportional amplifier. An amplification factor of the inverting proportional amplifier is 1. Subtracting the two signals removes a direct current component, and an alternating current portion becomes twice an original alternating current signal.

The inverting proportional amplifier includes the operational amplifier, a resistor R19, a resistor R20, and a resistor R23. The resistor R19 is connected to the inverting input terminal of the operational amplifier. The resistor R20 serves as the feedback resistor connecting the output terminal and the inverting input terminal of the operational amplifier. The resistor R23 connects the non-inverting input terminal of the operational amplifier to the input reference voltage or the ground, where resistance values of the resistor R19 and the resistor R20 are equal.

The moving-coil geophone zero-phase corrector based on the state variable shaper in the present disclosure further includes a single-supply and dual-supply mode selection module, providing selectable single-supply and dual-supply modes. Operational amplifiers may select a single-supply or dual-supply circuit structure via jumper caps. When operating in single-supply mode, a negative voltage terminal of the operational amplifier is connected to ground, and a non-inverting input terminal is connected to a reference voltage, namely half of the positive supply voltage. When operating in dual-supply mode, the negative voltage terminal of the operational amplifier is connected to a negative supply, and the non-inverting input terminal is connected to ground.

The beneficial effects of the present disclosure are as follows.

Compared with the prior art, the zero-phase correction method of the present disclosure, through the construction of the state variable shaper circuit, may perform phase characteristic correction on frequency responses with different phase characteristics. Furthermore, this circuit extends the low-frequency response of the geophone by constructing linear combinations of high-pass, band-pass, and low-pass filter circuits, thereby improving the quality and reliability of seismic data acquisition.

After correction by the phase correction circuit, the phase delay of the moving-coil geophone may be effectively compensated, correcting the phase to zero phase. Especially the phase delay in the low-frequency band is effectively controlled. While maintaining the gain in the original frequency band unchanged, the low-frequency response of the seismic geophone is extended, significantly expanding the application prospects of the moving-coil geophone in data processing, and further improving the application accuracy of the moving-coil geophone.

### BRIEF DESCRIPTION OF THE DRAWINGS

FIG. 1 is a schematic diagram of a moving-coil geophone.

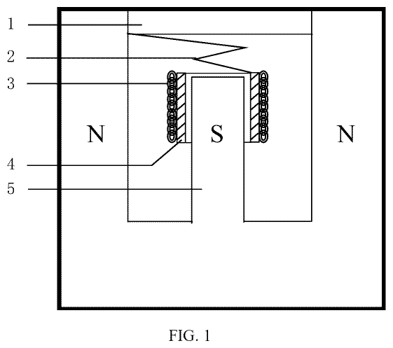

FIG. 2 is a Bode diagram of the geophone output transfer function.

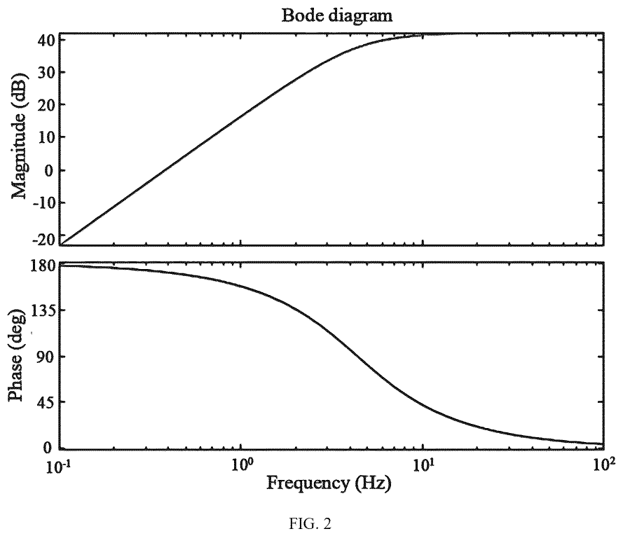

FIG. 3 is an overall block diagram of the phase correction.

FIG. 4 is a circuit schematic diagram of the differential-to-single-ended module.

FIG. 5 is a circuit schematic diagram of the state variable shaper.

FIG. 6 is a Bode diagram of the state variable shaper circuit.

FIG. 7 is a circuit schematic diagram of the single-ended-to-differential module.

FIG. 8 is a structure diagram of the single-supply and dual-supply mode selection.

### DETAILED DESCRIPTION OF THE EMBODIMENTS

The technical scheme of the present disclosure is further explained and described below in the form of specific embodiments.

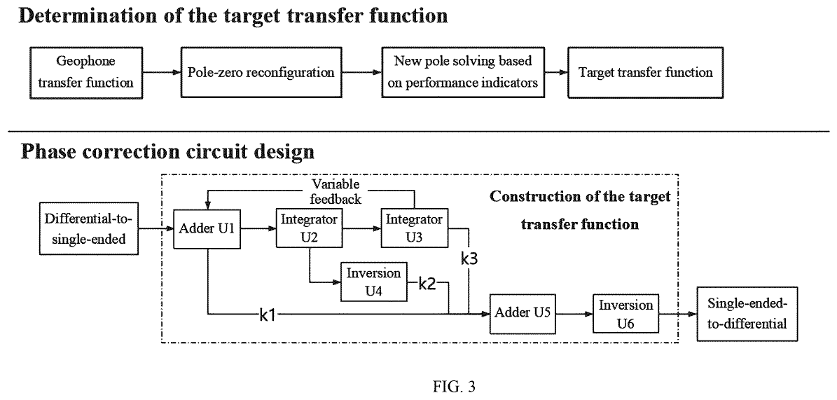

As shown in FIG. 3, a moving-coil geophone zero-phase corrector based on a state variable shaper according to the present disclosure is formed by connecting a differential-to-single-ended module, a state variable shaper module, and a single-ended-to-differential module. The detailed steps and methods for implementing these modules are as follows:

### 1. Differential-to-Single-Ended Module

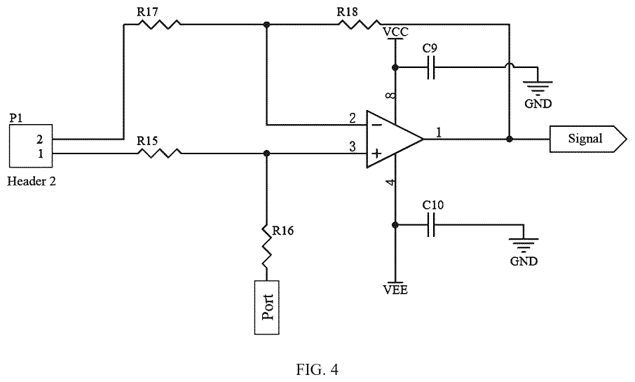

The circuit diagram of the differential-to-single-ended module is shown in FIG. 4. The differential-to-single-ended module is primarily a subtractor composed of an operational amplifier, a resistor R15, a resistor R16, a resistor R17, and a resistor R18. The resistor R15 is connected to the positive input signal terminal and is connected in parallel with the resistor R16 to the non-inverting input terminal of the operational amplifier. The resistor R16 is connected to ground or a reference voltage. The resistor R17 is connected to the negative input signal terminal and is connected in parallel with the resistor R18 to the inverting input terminal of the operational amplifier, converting the differential signal into a single-ended signal input to the state variable shaper module.

For simplified calculation and circuit balance, the resistance values of the resistors R15, R16, R17, and R18 in the circuit are set to have the following relationship: R18/R17=R16/R15. Under this condition, the circuit expression may be derived.

Let the positive terminal of the differential signal be V_{IN}⁺, and the negative terminal be V_{IN}⁻. The converted single-ended signal Vᵢ is then given by:

$${V}_{i} = \frac{{R}_{18}}{{R}_{17}} ( {V}_{IN}^{+} - {V}_{IN}^{-} )$$

The subtractor performs pre-processing on the differential signal, converting the differential signal into a single-ended signal suitable for the state variable shaper.

If the resistance values of the resistors R15, R16, R17, and R18 are made equal, the output single-ended signal becomes the difference between the differential signals V_{IN}⁺ and V_{IN}⁻.

### 2. State Variable Shaper Module Design

The state variable shaper is an important component of the present disclosure. The state variable shaper includes a high-pass filter, a band-pass filter, and a low-pass filter. Phase correction for the output of the moving-coil geophone is achieved through linear combination of the high-pass filter, band-pass filter, and low-pass filter. This system primarily corrects the phase within the 5 Hertz to 300 Hertz frequency band to address the phase delay issue of the moving-coil geophone. The core concept of the state variable shaper is to construct a transfer function through variable feedback control to compensate for the phase delay in the geophone's frequency response, ensuring that geophone's phase output remains at zero phase.

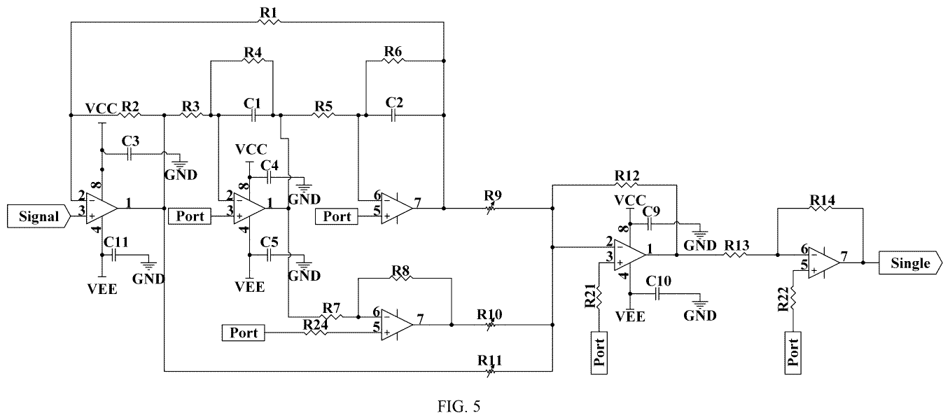

The circuit schematic of the state variable shaper is shown in FIG. 5. The circuit corrects the phase of the output signal of the moving-coil geophone using an adder, integrators, an inverting circuit, etc. Transfer functions for different requirements are constructed according to different summation coefficients, so that the phase meets the preset standard. Through this linear combination, the system may effectively correct the signal phase delay in the output of the moving-coil geophone.

Phase correction is achieved by summing the high-pass, band-pass, and low-pass outputs with different multiplication factors. The design of this process is completed through the following steps.

First, the transfer function of the geophone is fitted based on the frequency domain characteristics of the geophone's output signal, and the target transfer function of the phase corrector is designed based on the characteristics of the transfer function using the pole-zero compensation method. Second, the circuit structure and circuit parameters are designed according to the target transfer function.

The design of the circuit parameters is based on the target transfer function. The single-ended signal first enters the non-inverting terminal of the adder, and the high-pass filter characteristic is formed at the output terminal of the adder. The signal is integrated once by passing through the first integrator to form the band-pass filter characteristic, and the signal is integrated twice by passing through the second integrator to form the low-pass filter characteristic. The three output terminals with different characteristics output signals respectively and are connected to resistors with different resistance values. The signals are amplified by different factors and summed through a new adder, realizing the linear combination of the high-pass, band-pass, and low-pass filters. Finally, the phase change introduced by the adder is canceled by passing through an inverter. The transfer function H(s) of the circuit may be calculated using the current and voltage laws of the amplifier.

The following explains how to design the target transfer function of the state variable shaper based on the geophone transfer function, as shown in FIG. 3.

Since the moving-coil geophone has the characteristics of a second-order high-pass filter, the transfer function H₀(s) of the geophone is set as:

$${H}_{0} ( s ) = \frac{{A}_{0} {s}^{2}}{{s}^{2} + 2 {ξ}_{0} {ω}_{0} s + {ω}_{0}^{2}}$$

Then the phase characteristic φ₀(ω) of the geophone is:

$${φ}_{0} ( ω ) = arctan ( - \frac{2 {ξ}_{0} {ω}_{0} ω}{{ω}_{0}^{2} - {ω}^{2}} )$$

where s represents the frequency in the Laplace transform domain and is a complex variable, s=jω, A₀ is the gain of the transfer function of the moving-coil geophone, ω₀ is the cutoff frequency of the transfer function of the moving-coil geophone, and ξ₀ is the damping ratio.

To compensate the transfer function, the transfer function's poles and zeros must be reconfigured based on the pole-zero placement method. The target transfer function H₁(s) for zero-phase correction is set as:

$${H}_{1} ( s ) = \frac{{s}^{2} + As + B}{{s}^{2} + Cs + D}$$

Among them, A, B, C, and D are the unknown parameters of the constructed second-order system transfer function respectively.

The final obtained system transfer function H₂(s) is:

$${H}_{2} ( s ) = \frac{{A}_{0} {s}^{2}}{{s}^{2} + 2 {ξ}_{0} {ω}_{0} s + {ω}_{0}^{2}} \cdot \frac{{s}^{2} + As + B}{{s}^{2} + Cs + D}$$

In order to achieve the reconfiguration of poles and zeros and for system simplicity, A=2ξ₀ω₀, B=ω₀², C=2ξ₁ω₁, and D=ω₁² are set. Then the target transfer function H₁(s) for zero-phase correction is:

$${H}_{1} ( s ) = \frac{{s}^{2} + 2 {ξ}_{0} {ω}_{0} s + {ω}_{0}^{2}}{{s}^{2} + 2 {ξ}_{1} {ω}_{1} s + {ω}_{1}^{2}}$$

Among them, ω₁ is the cutoff frequency of the transfer function of the zero-phase correction circuit, ξ₁ and is the damping ratio.

The transfer function H₂(s) after the geophone is connected in series with the correction circuit is:

$${H}_{2} ( s ) = \frac{{A}_{0} {s}^{2}}{{s}^{2} + 2 {ξ}_{1} {ω}_{1} s + {ω}_{1}^{2}}$$

Therefore, the target transfer function may be determined immediately by confirming only the two unknowns, ξ₁ and ω₁. After the geophone undergoes series compensation, the system remains a second-order system. However, the denominator term of the geophone transfer function and the numerator term of the target transfer function cancel each other out, resulting in a new system that has a different natural frequency and damping ratio compared to the original geophone. When phase distortion occurs in the geophone, a target transfer function and a phase correction circuit are designed to correct the phase to zero within the desired frequency band. Then, after series compensation, the new system achieves zero-phase correction of the geophone signal while maintaining the original gain within the bandwidth, thereby broadening the effective frequency band of the geophone. The method is highly theoretical, convenient to design, has an intuitive expected effect, and offers various implementation methods, making it an ideal phase correction solution.

The phase ε of the system at 5 Hertz after phase correction is defined as the performance indicator for the correction effect, which is called the correction error. The phase correction requirement is considered met when ε is less than a certain range.

The phase characteristic φ₂(ω) of the final system transfer function H₂(s) is set to have a phase magnitude ≤ε at 5 Hertz, as shown in the following equation, where ω=2πf=10π.

$${φ}_{2} ( ω ) = arctan ( - \frac{2 {ξ}_{1} {ω}_{1} ω}{{ω}_{1}^{2} - {ω}^{2}} ) \leq ε$$

Since the system gain is related to the pole configuration of the transfer function and increases as ω₁ decreases, excessively large gain often introduces significant noise in hardware circuits. Therefore, the equality is taken in the above equation. If ξ₁ and ε are known, the target transfer function for phase correction and the final system transfer function may be solved. Consequently, the phase corrector based on the disclosure may perform phase correction on geophone signals with different transfer functions, demonstrating certain practicality.

The circuit connection of the phase corrector of the present disclosure is specifically described below. The system frequency characteristic of the state variable shaper module only considers 5 Hertz to 300 Hertz, and the state variable shaper module includes three parts: a high-pass filter, a band-pass filter, and a low-pass filter. The high-pass filter includes an adder U1, the band-pass filter includes an integrator U2 and an inverter U4, and the low-pass filter includes an integrator U3.

The adder U1 of the high-pass filter consists of an operational amplifier, a resistor R1, and a resistor R2. The resistor R1 serves as a feedback resistor connecting the inverting input terminal of the operational amplifier to the output terminal of the integrator U3. The resistor R2 connects the inverting input terminal of the adder U1 to the output terminal of the operational amplifier. The output terminal of the operational amplifier serves as the output port of the high-pass filter, and the phase at this port is substantially zero.

The integrator U2 of the band-pass filter consists of an operational amplifier, a resistor R3, a resistor R4, and a capacitor C1. The resistor R3 connects the output terminal of the adder U1 to the inverting input terminal of the operational amplifier. The resistor R4 and the capacitor C1 are connected in parallel as a feedback resistor and a feedback capacitor between the inverting input terminal and the output terminal of the operational amplifier, forming an inverting integrator. The output terminal of the integrator U2 exhibits the frequency characteristic of the band-pass filter and provides a phase lead of approximately 90 degrees. The output terminal of the integrator U2 is connected to the inverter U4. The inverter U4 consists of an operational amplifier, a resistor R7, a resistor R8, and a resistor R24. The resistor R7 connects the inverting input terminal of the operational amplifier to the output terminal of the integrator U2. The resistor R24 connects the non-inverting input terminal of the operational amplifier to an input reference voltage or ground. The resistor R8 serves as a feedback resistor connecting the inverting input terminal and the output terminal of the operational amplifier. The constituted inverter U4 ensures that the band-pass filter does not alter the phase characteristic.

The integrator U3 of the low-pass filter consists of an operational amplifier, a resistor R5, a resistor R6, and a capacitor C2. The resistor R5 connects the output terminal of the integrator U2 to the inverting input terminal of the operational amplifier. The resistor R6 and the capacitor C2 are connected in parallel as a feedback resistor and a feedback capacitor between the inverting input terminal and the output terminal of the operational amplifier. The output terminal of the integrator U3 exhibits the frequency characteristic of the low-pass filter and provides a phase lead of approximately 180 degrees.

The outputs of the high-pass filter, band-pass filter, and low-pass filter are connected to a resistor R9, a resistor R10, and a resistor R11 respectively. The resistors R9, R10, and R11 serve as resistors for the summation coefficients of the low-pass, band-pass, and high-pass filters respectively, determining the multiplication factors of these filters for summation. The resistors R9, R10, and R11 are connected to an adder U5 and an inverter U6.

In the adder U5, a resistor R12 serves as a feedback resistor connecting the output terminal and the inverting input terminal of the operational amplifier in the adder U5, determining the amplification factor during summation. A resistor R21 connects the non-inverting input terminal of the operational amplifier to an input reference voltage or ground.

The inverter U6 ensures that the phase does not change due to the presence of the adder. The inverter U6 consists of an operational amplifier, a resistor R13, a resistor R14, and a resistor R22. The resistor R13 connects the inverting input terminal of the operational amplifier to the output terminal of the adder U5. The resistor R22 connects the non-inverting input terminal of the operational amplifier to an input reference voltage or ground. The resistor R14 serves as a feedback resistor connecting the inverting input terminal and the output terminal of the operational amplifier.

The following explains how the circuit parameters of the state variable shaper are calculated based on the target transfer function.

According to the circuit structure of the state variable shaper, the formulas may be listed as follows:

$$\{ \begin{matrix}\frac{{V}_{3} - {V}_{i}}{{R}_{1}} = \frac{{V}_{i} - {V}_{1}}{{R}_{2}} \\ {V}_{3} = - \frac{{R}_{6}}{{R}_{5}} \frac{1}{{R}_{6} {C}_{2} j ω + 1} {V}_{2} \\ {V}_{2} = - \frac{{R}_{4}}{{R}_{3}} \frac{1}{{R}_{4} {C}_{1} j ω + 1} {V}_{1}\end{matrix}$$

Among them, Vᵢ is the output signal after differential-to-single-ended conversion, V₁ is the output of the high-pass filter, V₂ is the output of the band-pass filter, and V₃ is the output of the low-pass filter.

The relationship between the output of the high-pass filter and the input single-ended signal may be derived from the above formulas.

$$\frac{{V}_{1}}{{V}_{i}} = \frac{\frac{{R}_{1} + {R}_{2}}{{R}_{1}} ( {R}_{6} {C}_{2} j ω + 1 ) ( {R}_{4} {C}_{1} j ω + 1 )}{( {R}_{6} {C}_{2} j ω + 1 ) ( {R}_{4} {C}_{1} j ω + 1 ) + \frac{{R}_{2} {R}_{4} {R}_{6}}{{R}_{1} {R}_{3} {R}_{5}}}$$

Let s=jω, then the above equation may be written as the transfer function H_{H}(s) of the high-pass filter:

$${H}_{H} ( s ) = \frac{\frac{{R}_{1} + {R}_{2}}{{R}_{1}} ( {R}_{6} {C}_{2} s + 1 ) ( {R}_{4} {C}_{1} s + 1 )}{( {R}_{6} {C}_{2} s + 1 ) ( {R}_{4} {C}_{1} s + 1 ) + \frac{{R}_{2} {R}_{4} {R}_{6}}{{R}_{1} {R}_{3} {R}_{5}}}$$

Similarly, the transfer functions of the band-pass and low-pass filters are given by the following equations.

$${H}_{B} ( s ) = \frac{- \frac{{R}_{1} + {R}_{2}}{{R}_{1}} \frac{{R}_{4}}{{R}_{3}} ( {R}_{6} {C}_{2} s + 1 )}{( {R}_{6} {C}_{2} s + 1 ) ( {R}_{4} {C}_{1} s + 1 ) + \frac{{R}_{2} {R}_{4} {R}_{6}}{{R}_{1} {R}_{3} {R}_{5}}}$$

$${H}_{L} ( s ) = \frac{\frac{{R}_{1} + {R}_{2}}{{R}_{1}} \frac{{R}_{4}}{{R}_{3}} \frac{{R}_{6}}{{R}_{5}}}{( {R}_{6} {C}_{2} s + 1 ) ( {R}_{4} {C}_{1} s + 1 ) + \frac{{R}_{2} {R}_{4} {R}_{6}}{{R}_{1} {R}_{3} {R}_{5}}}$$

The transfer function of the band-pass filter is negative, which is inconsistent with the transfer functions of the other filters. Therefore, an inverter is added to change the negative transfer function to a positive transfer function. The parameters remain unchanged, ensuring the accuracy of the transfer function phase.

The summation coefficients for the high-pass filter, band-pass filter, and low-pass filter are set as K1, K2, and K3 respectively, and their relationship with the resistors R9, R10, R11, and R12 is given by the following equations.

$$\{ \begin{matrix}K 1 = \frac{{R}_{12}}{{R}_{11}} \\ K 2 = \frac{{R}_{12}}{{R}_{10}} \\ K 3 = \frac{{R}_{12}}{{R}_{9}}\end{matrix}$$

Therefore, the final circuit transfer function is:

$$H ( s ) = K 1 * {H}_{H} ( s ) + K 2 * {H}_{B} ( s ) + K 3 * {H}_{L} ( s ) = \frac{\begin{matrix}K 1 * \frac{{R}_{1} + {R}_{2}}{{R}_{2}} ( {R}_{6} {C}_{2} s + 1 ) ( {R}_{4} {C}_{1} s + 1 ) + \\ K 2 * \frac{{R}_{1} + {R}_{2}}{{R}_{1}} \frac{{R}_{4}}{{R}_{3}} ( {R}_{6} {C}_{2} s + 1 ) + K 3 * \frac{{R}_{1} + {R}_{2}}{{R}_{1}} \frac{{R}_{4}}{{R}_{3}} \frac{{R}_{6}}{{R}_{5}}\end{matrix}}{( {R}_{6} {C}_{2} s + 1 ) ( {R}_{4} {C}_{1} s + 1 ) + \frac{{R}_{2} {R}_{4} {R}_{6}}{{R}_{1} {R}_{3} {R}_{5}}}$$

The cutoff frequency of the transfer function H(s) is

$${ω}_{c} = \sqrt{\frac{1}{{R}_{4} {R}_{6} {C}_{1} {C}_{2}} + \frac{{R}_{2}}{{R}_{1} {R}_{3} {R}_{5} {C}_{1} {C}_{2}}} .$$

By setting H(s)=H₁(s), the circuit parameters may be solved, and zero-phase correction of the geophone may be performed using the solved circuit parameters.

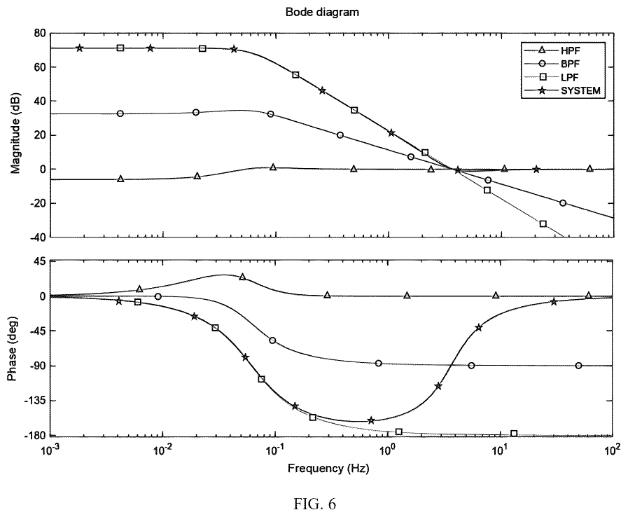

The Bode diagram of the state variable shaper is shown in FIG. 6. HPF represents the frequency domain characteristic curve of the high-pass output, BPF represents the frequency domain characteristic curve of the band-pass output, LPF represents the frequency domain characteristic curve of the low-pass output, and SYSTEM represents the Bode diagram of the target transfer function when all summation coefficients are set to 1.

The design of the transfer function is based on the pole-zero placement method. The dynamic response characteristics of the system are adjusted by reconfiguring the poles and zeros. The denominator of the original moving-coil geophone transfer function is set as the numerator, and a new damping ratio and cutoff frequency are designed as the poles for phase correction.

In practice, the design concept of the target transfer function is to approximate the inverse phase of the original moving-coil geophone transfer function. The sum of the two phases becomes zero phase, thus meeting the requirement. Therefore, zero-phase correction based on the pole-zero placement method uses poles to cancel zeros. The frequency response within the 5 Hertz to 300 Hertz range increases as the frequency increases, and the phase remains consistently negative within this frequency band. This characteristic is opposite to the phase delay of the geophone and may be used to correct the phase delay issue of the geophone.

The phase characteristic φ₁(ω) of the target transfer function H₁(s) is given by the following formula:

$${φ}_{1} ( ω ) = arctan ( - \frac{2 {ξ}_{0} {ω}_{0} ω ( {ω}_{1}^{2} - {ω}^{2} ) - 2 {ξ}_{1} {ω}_{1} ω ( {ω}_{0}^{2} - {ω}^{2} )}{( {ω}_{0}^{2} - {ω}^{2} ) ( {ω}_{1}^{2} - {ω}^{2} ) + 4 {ξ}_{0} {ω}_{0} {ξ}_{1} {ω}_{1} {ω}^{2}} )$$

It may be seen from the formula that the phase characteristic is consistently less than zero within the 5 Hertz to 300 Hertz range, and the phase characteristic approaches zero infinitely as the frequency becomes higher. The phase gradually decreases as the frequency becomes lower. Therefore, when ξ₀ and ω₀ are known, appropriate parameters ξ₁ and ω₁ may be determined so that the phase of the target transfer function is opposite to the output phase of the moving-coil geophone, and effective correction of the geophone's phase characteristic is achieved.

The zero-phase correction circuit based on the state variable shaper designed by the staff may achieve the phase inversion of the original moving-coil geophone output. The circuit is connected in series with the geophone, and the phases of the two are added together to ultimately correct the final phase to zero. The zeros of the final system's transfer function remain unchanged while the poles change. Additionally, no extra gain is introduced to the moving-coil geophone output, the gain within the frequency band is maintained, and the low-frequency response of the geophone is extended.

In the highly complex and precise frontier scientific field of modern signal processing, high-pass, band-pass, and low-pass filters serve as fundamental key architectures, providing solid support for the entire signal processing system. It is noted that the transfer functions of the high-pass, band-pass, and low-pass filters share the same cutoff frequency. The overall transfer function for phase correction exhibits a phase lead characteristic within the 5 Hertz to 300 Hertz frequency band. When the circuit is connected in series with the geophone, the two second-order systems are cascaded, and the result remains a second-order system. The denominator term of the moving-coil geophone transfer function and the numerator term of the phase correction transfer function cancel each other out. The resulting new system has a different natural frequency and damping ratio compared to the original geophone. This new system may correct the phase characteristics of the second-order high-pass filter present in the geophone's output frequency response. Furthermore, since the coefficients of the highest-order terms in both the numerator and denominator of the target transfer function H₁(s) are 1, the phase correction does not affect the gain within the frequency band. The original gain of the geophone is maintained, while the magnitude plot exhibits low-frequency compensation characteristics, enabling an extension of the geophone's low-frequency response. After series compensation, the damping ratio is improved, the equivalent natural frequency is reduced, and low-frequency characteristic compensation is achieved. This broadens the effective frequency band of the moving-coil geophone without requiring any modifications to its internal structure.

For different outputs of moving-coil geophones, different target transfer functions are determined. Different values of K1, K2, and K3 may be changed to construct different transfer functions for correcting different phase characteristics. This achieves the correction of the output phase characteristics of the moving-coil geophone. When the summation coefficients are different, the phase correction characteristics in the circuit change accordingly. These characteristics are opposite to the output phase of the moving-coil geophone, thus achieving the correction purpose. Also, due to the change in summation coefficients, this circuit may flexibly construct different transfer functions H(S) according to different summation coefficients, making it suitable for moving-coil geophones with different phase characteristics.

### 3. Single-Ended-to-Differential Module

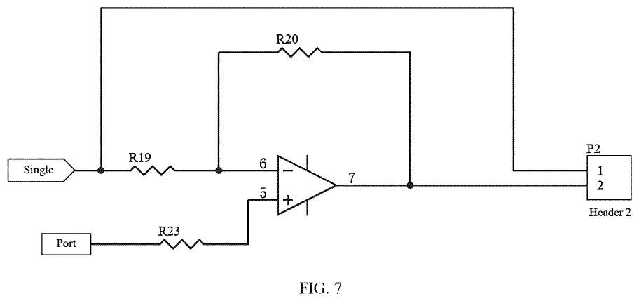

The circuit diagram of the single-ended-to-differential module is shown in FIG. 7. The single-ended-to-differential module includes an inverting proportional amplifier. One path of the single-ended output signal is directly connected to the positive output terminal, and the other path is connected to the negative output terminal through the inverting proportional amplifier. The amplification factor of the inverting proportional amplifier is 1. The direct current component is removed by subtracting the two signals, and the alternating current portion becomes twice the original alternating current signal.

The inverting proportional amplifier consists of an operational amplifier, a resistor R19, a resistor R20, and a resistor R23. The resistor R19 is connected to the inverting input terminal of the operational amplifier. The resistor R20 serves as a feedback resistor connecting the output terminal and the inverting input terminal of the operational amplifier. The resistor R23 connects the non-inverting input terminal of the operational amplifier to an input reference voltage or ground.

For simplified calculation and circuit balance, the resistance values of the resistor R19 and the resistor R20 in the circuit are made equal. Under this condition, the circuit expression may be derived. Let the single-ended output signal of the circuit be V₀. Then the positive terminal of the output differential signal is V_{OUT}⁺, and the negative terminal is V_{OUT}⁻, which are given as follows:

$$\{ \begin{matrix}{V}_{OUT}^{+} = {V}_{0} \\ {V}_{OUT}^{-} = - {V}_{0}\end{matrix}$$

The inverter inverts the single-ended signal, so that the positive terminal of the differential signal is the single-ended signal itself, and the negative terminal is the inverted single-ended signal. The difference between the two is twice the original output signal.

### 4. Single-Supply and Dual-Supply Mode Selection Module

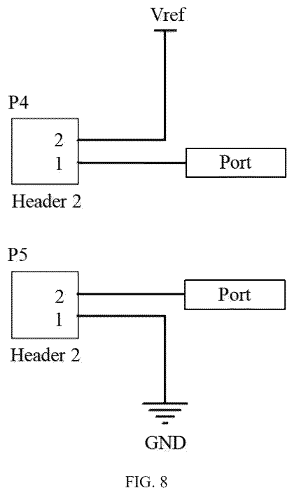

The circuit of the single-supply and dual-supply mode selection module is shown in FIG. 8. A jumper cap method is used for selection. Port represents the reference voltage of the operational amplifier. When the single-supply mode is selected, the VEE terminal of the operational amplifier is connected to ground, the jumper cap is placed on P4, and the reference voltage Vref is selected. When the dual-supply mode is selected, the VEE terminal of the operational amplifier is connected to the negative supply, the jumper cap is placed on P5, and the reference voltage is selected to be ground.

Through the above method, zero-phase correction for the phase delay of the moving-coil geophone is achieved. The phase stability of the system output is improved, and the quality and reliability of seismic data acquisition are significantly enhanced. It is worth emphasizing that our method effectively corrects the phase delay issue in the output of the moving-coil geophone while simultaneously compensating for the low-frequency response. For different models of moving-coil geophones with different phase delays, the circuit transfer function may be altered by changing the summation coefficients. This makes the method applicable to moving-coil geophones with different transfer functions, enabling phase characteristic correction within the 5 Hertz to 300 Hertz frequency band. This zero-phase correction method for moving-coil geophones based on the state variable shaper possesses real-time capability and reliability. It may effectively correct phase delays, improve the performance indicators of the moving-coil geophone, and expand the application range of the moving-coil geophone.

What is claimed is:

1. A moving-coil geophone zero-phase corrector based on a state variable shaper, formed by connecting a differential-to-single-ended module, a state variable shaper module, and a single-ended-to-differential module in sequence;
wherein the state variable shaper module is designed for a frequency range of 5-300 Hertz, and comprises a high-pass filter, a band-pass filter, and a low-pass filter, the high-pass filter comprises an adder (U1), the band-pass filter comprises an integrator (U2) and an inverter (U4), and the low-pass filter comprises an integrator (U3);
the adder (U1) of the high-pass filter comprises a first operational amplifier, a resistor (R1), and a resistor (R2), the resistor (R1) serves as a feedback resistor connecting an inverting input terminal of the first operational amplifier to an output terminal of the integrator (U3), the resistor (R2) connects an inverting input terminal of the adder (U1) to an output terminal of the first operational amplifier, the output terminal of the first operational amplifier serves as an output port of the high-pass filter, and a phase at the output port is substantially zero;
the integrator (U2) of the band-pass filter comprises a second operational amplifier, a resistor (R3), a resistor (R4), and a capacitor (C1), the resistor (R3) connects an output terminal of the adder (U1) to an inverting input terminal of the second operational amplifier, the resistor (R4) and the capacitor (C1) are connected in parallel as the feedback resistor and a feedback capacitor between the inverting input terminal and an output terminal of the second operational amplifier, forming an inverting integrator, an output terminal of the integrator (U2) exhibits a frequency characteristic of the band-pass filter and provides a phase lead of approximately 90 degrees, the output terminal of the integrator (U2) is connected to the inverter (U4), the inverter (U4) comprises a third operational amplifier, a resistor (R7), a resistor (R8), and a resistor (R24), the resistor (R7) connects an inverting input terminal of the third operational amplifier to the output terminal of the integrator (U2), the resistor (R24) connects a non-inverting input terminal of the third operational amplifier to an input reference voltage or ground, the resistor (R8) serves as the feedback resistor connecting the inverting input terminal and an output terminal of the third operational amplifier, and the constituted inverter (U4) ensures a band-pass filter phase characteristic unaltered;
the integrator (U3) of the low-pass filter comprises a fourth operational amplifier, a resistor (R5), a resistor (R6), and a capacitor (C2), the resistor (R5) connects the output terminal of the integrator (U2) to an inverting input terminal of the fourth operational amplifier, the resistor (R6) and the capacitor (C2) are connected in parallel as the feedback resistor and the feedback capacitor between the inverting input terminal and an output terminal of the fourth operational amplifier, and the output terminal of the integrator (U3) exhibits a frequency characteristic of the low-pass filter and provides a phase lead of approximately 180 degrees;
outputs of the high-pass filter, the band-pass filter, and the low-pass filter are connected to a resistor (R9), a resistor (R10), and a resistor (R11) respectively, the resistor (R9), the resistor (R10), and the resistor (R11) serve as resistors determining weighting coefficients for summing the low-pass filter, the band-pass filter, and the high-pass filter respectively to set filter multiplication factors for summation, and the resistor (R9), the resistor (R10), and the resistor (R11) are connected to an adder (U5) and an inverter (U6);
a resistor (R12) in the adder (U5) serves as a feedback resistor connecting an output terminal of a fifth operational amplifier and an inverting input terminal of the fifth operational amplifier in the adder (U5), determining an amplification factor during the summation, and a resistor (R21) connects a non-inverting input terminal of the fifth operational amplifier to the input reference voltage or the ground;
the inverter (U6) ensures phase stability despite adder presence, the inverter (U6) comprises a sixth operational amplifier, a resistor (R13), a resistor (R14), and a resistor (R22), the resistor (R13) connects an inverting input terminal of the sixth operational amplifier to an output terminal of the adder (U5), the resistor (R22) connects a non-inverting input terminal of the sixth operational amplifier to the input reference voltage or the ground, and the resistor (R14) serves as the feedback resistor connecting the inverting input terminal and an output terminal of the sixth operational amplifier;
a transfer function of the state variable shaper module is as follows:
$$H ( s ) = K 1 * {H}_{H} ( s ) + K 2 * {H}_{B} ( s ) + K 3 * {H}_{L} ( s ) \qquad ( 1 )$$
wherein s represents a frequency in a Laplace transform domain, K1, K2, and K3 are summation coefficients for the high-pass filter, the band-pass filter, and the low-pass filter respectively, different summation coefficients correspond to different linear combinations, by changing the summation coefficients, a transfer function constructed by a circuit is altered to achieve phase characteristic correction for an output frequency response of different geophones, and the summation coefficients K1, K2, and K3 adhere to a following relationship:
$$\{ \begin{matrix}K 1 = \frac{{R}_{12}}{{R}_{11}} \\ K 2 = \frac{{R}_{12}}{{R}_{10}} \\ K 3 = \frac{{R}_{12}}{{R}_{9}}\end{matrix} \qquad ( 2 )$$
wherein R9 represents a resistance value of the resistor (R9), R10 represents a resistance value of the resistor (R10), and R11 represents a resistance value of the resistor (R11);
in equation (1), H_{H}(s), H_{B}(s), and H_{L}(s) are transfer functions of the high-pass filter, the band-pass filter, and the low-pass filter respectively, expressed as:
$${H}_{H} ( s ) = \frac{\frac{{R}_{1} + {R}_{2}}{{R}_{1}} ( {R}_{6} {C}_{2} s + 1 ) ( {R}_{4} {C}_{1} s + 1 )}{( {R}_{6} {C}_{2} s + 1 ) ( {R}_{4} {C}_{1} s + 1 ) + \frac{{R}_{2} {R}_{4} {R}_{6}}{{R}_{1} {R}_{3} {R}_{5}}} \qquad ( 3 )$$
$${H}_{B} ( s ) = \frac{- \frac{{R}_{1} + {R}_{2}}{{R}_{1}} \frac{{R}_{4}}{{R}_{3}} ( {R}_{6} {C}_{2} s + 1 )}{( {R}_{6} {C}_{2} s + 1 ) ( {R}_{4} {C}_{1} s + 1 ) + \frac{{R}_{2} {R}_{4} {R}_{6}}{{R}_{1} {R}_{3} {R}_{5}}} \qquad ( 4 )$$
$${H}_{L} ( s ) = \frac{\frac{{R}_{1} + {R}_{2}}{{R}_{1}} \frac{{R}_{4}}{{R}_{3}} \frac{{R}_{6}}{{R}_{5}}}{( {R}_{6} {C}_{2} s + 1 ) ( {R}_{4} {C}_{1} s + 1 ) + \frac{{R}_{2} {R}_{4} {R}_{6}}{{R}_{1} {R}_{3} {R}_{5}}} \qquad ( 5 )$$
in transfer functions equations (3) to (5), C1 represents a capacitance of the capacitor (C1), C2 represents a capacitance of the capacitor (C2), R1 represents a resistance value of the resistor (R1), R2 represents a resistance value of the resistor (R2), R3 represents a resistance value of the resistor (R3), R4 represents a resistance value of the resistor (R4), R5 represents a resistance value of the resistor (R5), and R6 represents a resistance value of the resistor (R6);
H₁(s) represents a target transfer function used for zero-phase correction, and H₂(s) represents a transfer function after cascading the moving-coil geophone zero-phase corrector, expressed as:
$${H}_{1} ( s ) = \frac{{s}^{2} + 2 {ξ}_{0} {ω}_{0} s + {ω}_{0}^{2}}{{s}^{2} + 2 {ξ}_{1} {ω}_{1} s + {ω}_{1}^{2}} \qquad ( 6 )$$
$${H}_{2} ( s ) = \frac{{S}_{0} {s}^{2}}{{s}^{2} + 2 {ξ}_{1} {ω}_{1} s + {ω}_{1}^{2}} \qquad ( 7 )$$
in equation (6), ω₀ and ξ₀ are a cutoff frequency and a damping ratio of a transfer function of a moving-coil geophone respectively, ω₁ and ξ₁ are a cutoff frequency and a damping ratio of a transfer function of a zero-phase correction circuit respectively; and in equation (7), A₀ is a gain of the transfer function of the moving-coil geophone;
H(S)=H₁(s) is set, and reasonable design and selection of resistor and capacitor parameters are combined, then the parameters C1, C2, R1, R2, R3, R4, R5, R6, R9, R10, R11, K1, K2, and K3 in above transfer function equations are solved, thus zero-phase correction of a geophone is enabled using solved circuit parameters; and
a phase characteristic φ₂(ω) of the transfer function H₂(s) after cascading the geophone and the zero-phase correction circuit is set to have a phase magnitude of F at 5 Hertz, as follows:
$${φ}_{2} ( ω ) = arctan ( - \frac{2 {ξ}_{1} {ω}_{1} ω}{{ω}_{1}^{2} - {ω}^{2}} ) = ε$$
with ξ₁ and ε known, ω₁ is solved to determine the target transfer function H₁(s) for the zero-phase correction.

2. The moving-coil geophone zero-phase corrector based on the state variable shaper according to claim 1, wherein
the differential-to-single-ended module comprises a seventh operational amplifier, a resistor (R15), a resistor (R16), a resistor (R17), and a resistor (R18), wherein the resistor (R15) is connected to a positive input signal terminal and is connected in parallel with the resistor (R16) to a non-inverting input terminal of the seventh operational amplifier, the resistor (R16) is connected to the ground or a reference voltage, the resistor (R17) is connected to a negative input signal terminal and is connected in parallel with the resistor (R18) to an inverting input terminal of the seventh operational amplifier, a single-ended signal is input to the state variable shaper module, and resistance values of the resistor (R15), the resistor (R16), the resistor (R17), and the resistor (R18) are equal.

3. The moving-coil geophone zero-phase corrector based on the state variable shaper according to claim 1, wherein
the single-ended-to-differential module comprises an inverting proportional amplifier, a path of a single-ended output signal is directly connected to a positive output terminal, and another path of the single-ended output signal is connected to a negative output terminal through the inverting proportional amplifier, an amplification factor of the inverting proportional amplifier is 1, subtracting the two paths of the single-ended output signal removes a direct current component, and an alternating current portion becomes twice an original alternating current signal.

4. The moving-coil geophone zero-phase corrector based on the state variable shaper according to claim 3, wherein
the inverting proportional amplifier comprises an eighth operational amplifier, a resistor (R19), a resistor (R20), and a resistor (R23), the resistor (R19) is connected to an inverting input terminal of the eighth operational amplifier, the resistor (R20) serves as the feedback resistor connecting an output terminal and the inverting input terminal of the eighth operational amplifier, and the resistor (R23) connects a non-inverting input terminal of the eighth operational amplifier to the input reference voltage or the ground, wherein resistance values of the resistor (R19) and the resistor (R20) are equal.

5. The moving-coil geophone zero-phase corrector based on the state variable shaper according to claim 3, wherein the moving-coil geophone zero-phase corrector based on the state variable shaper further comprises a single-supply and dual-supply mode selection module, the single-supply and dual-supply mode selection module provides selectable single-supply and dual-supply modes for operational amplifiers in the differential-to-single-ended module, the state variable shaper module, and the single-ended-to-differential module, the differential-to-single-ended module, the state variable shaper module, and the single-ended-to-differential module select a single-supply or dual-supply circuit structure via jumper caps; when operating in the single-supply mode, negative voltage terminals of the operational amplifiers are connected to the ground, and non-inverting input terminals of the operational amplifiers are connected to a reference voltage, namely half of a positive supply voltage; and when operating in the dual-supply mode, the negative voltage terminals of the operational amplifiers are connected to a negative supply, and the non-inverting input terminals of the operational amplifiers are connected to the ground.
